(19) United States
(12) Patent Application Publication
(10) Pub. No.: US 2022/0068740 A1
(43) Pub. Date: Mar. 3, 2022

(54) SEMICONDUCTOR SYSTEM AND METHOD OF FORMING SEMICONDUCTOR SYSTEM

(71) Applicant: Intel Corporation, Santa Clara, CA (US)

(72) Inventors: Jackson Chung Peng KONG, Tanjung Tokong Pulau Pinang (MY); Bok Eng CHEAH, Gelugor Pulau Pinang (MY); Seok Ling LIM, Kulim Kedah (MY); Jenny Shio Yin ONG, Bayan Lepas Pulau Pinang (MY)

(21) Appl. No.: 17/088,621

(22) Filed: Nov. 4, 2020

(30) Foreign Application Priority Data
Aug. 28, 2020 (MY) PI2020004456

(51) Int. Cl. H01L 23/31; H01L 23/538; H01L 23/14; H01R 12/71

(52) U.S. Cl. CPC H01L 23/31; H01L 23/5385; H01R 12/716; H01L 23/14; H01L 23/5384

(57) ABSTRACT

According to various examples, a device is described. The device may include a printed circuit board. The device may include a semiconductor package including an interposer with a molded portion, and one or more of semiconductor devices. The one or more semiconductor devices may have at least a first device coupled to the molded portion. The device may include a first connector coupled to the molded portion, and a second connector coupled to the printed circuit board, the first connector and the second connector configured to be connected with a cable for signal connection between the first device and the printed circuit board.

### CROSS-REFERENCE TO RELATED APPLICATIONS

This non-provisional application claims priority to Malaysian Application PI2020004456, which was filed on Aug. 28, 2020, which is incorporated by reference herein in its entirety.

### BACKGROUND

Conventional interconnect designs, e.g., 224G serializer/deserializer (SerDes) Ethernet, 40G Thunderbolt (TBT), and 32G peripheral component interconnect express (PCIe) GenS, have signals propagating through extensive transmission lines across the package substrate to a printed circuit board (PCB) and through multiple interconnect transitions, e.g., vertical vias, capacitive solder balls, sockets and/or plated-through-hole (PTH) structures used in conventional interconnect designs in a computing system, e.g., high-end desktop and server platforms. Due to the resistance and capacitance (RC) parasitic effects of the multiple interconnect transitions, there are electrical impairments, in terms of attenuation losses and multi-reflection noises, that may not allow the scaling of the performance of high-speed input/output (I/O) in a 2.5D/3D stacked die packaging system at a signal frequency of more than 40 GHz.

The existing on-package connector solutions to mitigate interconnects losses for high-speed bus applications include direct mounting of an electrical connector on the package substrate adjacent to the silicon device to circumvent electrical losses associated with a PCB routing, and using package-to-PCB interconnections. However, this may result in the consumption of additional package substrate footprint required for component mounting, e.g., mounting pads and/or mechanical retention structures. This may also result in electrical losses ascribed to package-to-chiplet interconnects, e.g., package routing, through-silicon-via (TSV), and interposer redistribution layer (RDL) for 2.5D and 3D packaging system, which makes interconnect bandwidth scaling difficult.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 shows a cross-sectional view of a semiconductor system according to an aspect of the present disclosure;

FIG. 2 shows a flow chart illustrating a method of forming a device according to an aspect of the present disclosure.

FIG. 3 shows a cross-sectional view of a semiconductor system according to an aspect of the present disclosure;

FIG. 4 shows a top view of the semiconductor system of FIG. 3 according to an aspect of the present disclosure;

FIGS. 5A through 5G show cross-sectional views directed to an exemplary process flow for a method of forming a semiconductor system according to an aspect of the present disclosure; and

FIG. 6 shows an illustration of a computing device that includes a semiconductor system according to a further aspect of the present disclosure.

### DETAILED DESCRIPTION

The following detailed description refers to the accompanying drawings that show, by way of illustration, specific details and aspects in which the present disclosure may be practiced. These aspects are described in sufficient detail to enable those skilled in the art to practice the present disclosure. Various aspects are provided for the present devices, and various aspects are provided for the methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

An advantage of the present disclosure may include improved signal integrity performance for high-speed signaling for next-generation multi-gigabits per second (Gbps) SerDes, TBT, and PCIe signals. Improved signal integrity performance may be achieved by circumventing attenuation and/or reflection losses ascribed to package routing, package-to-motherboard vertical interconnects, e.g., ball grid array (BGA), plated-through-hole (PTH) and PCB routing. This may allow device bandwidth scaling and/or more power-efficient circuitry design.

Another advantage of the present disclosure may include improved power integrity performance through circumvention of extensive power loop inductance ascribed to package and PCB power delivery network (PDN). This may result in reduced power supply noise (PSN) jitter, and decoupling capacitor components for device miniaturization.

Another advantage of the present disclosure may include package miniaturization through reduced package form-factor by the elimination of footprint required for connector contact pads, retention mechanisms, and reduction of platform components, e.g., a re-timer or re-driver component, that are required to amplify the transmitted high-speed signals.

Another advantage of the present disclosure may include improved radiofrequency interference (RFI) or electromagnetic interference (EMI) performance through the reduction of energy or radiation coupling from high-speed signal to sensitive interfaces, e.g., a reference clock signal or wireless signals across the package and motherboard interconnects.

The present disclosure generally relates to a device. The device may include a printed circuit board. The device may include a semiconductor package including an interposer with a molded portion, and one or more of semiconductor devices. The one or more semiconductor devices may have at least a first device coupled to the molded portion. The device may include a first connector coupled to the molded portion, and a second connector coupled to the printed circuit board, the first connector and the second connector configured to be connected with a cable for signal connection between the first device and the printed circuit board.

The present disclosure generally relates to a method of forming a device. The method may include providing an interposer for a semiconductor package. The method may include forming a molded portion extending from the interposer. The method may include forming a mold cavity in the molded portion. The method may include providing a package substrate with a first connector. The method may include aligning the mold cavity to position the first connector therein. The method may include providing a printed circuit board including a second connector coupled thereon. The method may include providing a cable with a first fastener attached to a first end of the cable and a second fastener attached to a second end of the cable. The method may include attaching the first fastener to the first connector. The method may include attaching the second fastener to the second connector.

The present disclosure generally relates to a computing device. The computing device may include a printed circuit board coupled to the computing device. The computing device may include a semiconductor package including an interposer with a molded portion, and one or more of semiconductor devices. The one or more semiconductor devices may have at least a first device coupled to the molded portion. The computing device may include a first connector coupled to the molded portion, and a second connector coupled to the printed circuit board, the first connector and the second connector configured to be connected with a cable for signal connection between the first device and the printed circuit board.

To more readily understand and put into practical effect, the present device, computing device, method, and other particular aspects will now be described by way of examples and not limitations, and with reference to the figures. For the sake of brevity, duplicate descriptions of features and properties may be omitted.

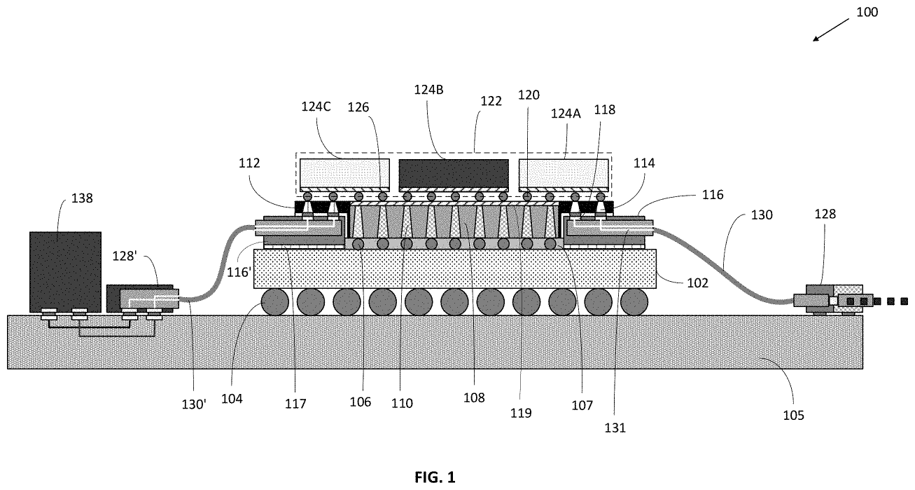

FIG. 1 shows a cross-sectional view of a semiconductor system according to an aspect of the present disclosure.

In an aspect of the present disclosure, a semiconductor system 100 is shown in FIG. 1. The semiconductor system 100 may be a device. The semiconductor system 100 may include a semiconductor package, e.g., a stacked semiconductor package like a 2.5D or a 3D semiconductor package.

In an aspect of the present disclosure, the semiconductor system 100 may include a package substrate 102. The package substrate 102 may include contact pads, electrical interconnects, routings, and other features, which are not shown in any of the present figures. The package substrate 102 may have one or more rigid core layer for improved structural stability or a coreless substrate package for a reduced form-factor. In other aspects, the package substrate 102 may be part of a larger substrate that supports additional semiconductor packages, and/or components.

In an aspect of the present disclosure, the semiconductor system 100 may include a plurality of solder balls 104. The package substrate 102 may be connected to a motherboard 105 through the plurality of solder balls 104. The motherboard 105 may be a PCB. In an aspect, the plurality of solder balls 104 may provide an electrical connection between the package substrate 102, and the motherboard 105.

In an aspect of the present disclosure, the semiconductor system 100 may include a plurality of package bumps 106 disposed on the package substrate 102. The plurality of package bumps 106 may be controlled collapse chip connection (C4) bumps. In an aspect, an underfill layer 107 may be deposited to cover, and to protect the plurality of package bumps 106 in a conventional manner. The underfill layer 107 may be provided to add strength to the semiconductor system 100. The underfill layer 107 may be provided using either a conventional underfilling process or no-flow underfilling process to reduce the effects of thermal expansion and reduce the stress and strain on the package bumps 106.

In an aspect of the present disclosure, the semiconductor system 100 may include an interposer 108. The interposer 108 may be an electrical interface routing between one connection to another. The purpose of the interposer 108 may be to redistribute a connection to a wider pitch or to reroute a connection to a different connection. The interposer 108 may be an active interposer or a passive interposer. The interposer 108 may be a silicon or organic interposer.

In an aspect of the present disclosure, the interposer 108 may be disposed on the package substrate 102. In an aspect, the interposer 108 may be connected to the package substrate 102 through the plurality of package bumps 106. The plurality of package bumps 106 may also provide an electrical connection between the interposer 108, and the package substrate 102.

In an aspect of the present disclosure, the interposer 108 may include at least one TSV 110. The plurality of package bumps 106 may provide an electrical connection between the at least one TSV 110, and the package substrate 102. Each TSV 110 may be correspondingly coupled to a package bump 106 of the plurality of package bumps 106.

In an aspect of the present disclosure, the semiconductor system 100 may include a first connector 116. In an aspect, the first connector 116 may be disposed on the package substrate 102. In an aspect, the first connector 116 may be attached to the package substrate 102 through an adhesive layer 117. In an aspect, the first connector 116 may be disposed adjacent to the interposer 108. In an aspect, the first connector 116 may be an interposer connector.

In an aspect of the present disclosure, the semiconductor system 100 may include a second connector 128. In an aspect, the second connector 128 may be mounted on the motherboard 105. In an aspect, the second connector 128 may be electrically connected to the motherboard 105. In an aspect, the second connector 128 may be an external connector, e.g., a passive connector, or a transceiver device. In an aspect, the second connector 128 may be connected to an external signal component. The external signal component may provide signals to the semiconductor system 100. In an aspect, the second connector 128 may be connected to a power supply component, e.g., a voltage regulator for reduced AC power loop inductance. The power supply component may be mounted on the motherboard 105.

In an aspect of the present disclosure, the semiconductor system 100 may include a molded portion 112. In an aspect, the molded portion 112 may be disposed on the first connector 116. In an aspect, the molded portion 112 may be disposed adjacent to the interposer 108. In an aspect, the molded portion 112 may be disposed at a periphery of the interposer 108. In an aspect, the molded portion 112 may have a mold cavity. In an aspect, the molded portion 112 may have a first portion, and a second portion. The first portion of the molded portion 112 may have a thickness larger than a thickness of the second portion of the molded portion 112. The first portion of the molded portion 112 may be disposed at a periphery of the interposer 108. The first portion of the molded portion 112 may surround at least one periphery sidewall of the interposer 108. In an aspect, the mold cavity may be below the second portion of the molded portion 112. In an aspect, the first connector 116 may be positioned in the mold cavity. The first connector 116 may be coupled to the molded portion, e.g., to the second portion of the molded portion 112.

In an aspect of the present disclosure, the molded portion 112 may include at least one molded via 114. In an aspect, the molded portion 112 may include molding material such as a thermosetting polymer e.g., epoxy resins, polyester resin, vinyl ester, or a ceramic polymer layer. The molded portion 112 may have a first mold surface coupled to the first connector 116. The molded portion 112 may have a second mold surface coupled to the one or more semiconductor device 122. In an aspect, the second mold surface may be adjacent to an interposer chiplet surface. In an aspect, the at least one molded via 114 may be embedded in the molding material of the molded portion 112. The at least one molded via 114 may extend through the first mold surface, and the second mold surface. In an aspect, the molded via 114 may be in the second portion of the molded portion 112.

In an aspect of the present disclosure, the first connector 116 may have a first side and a second side. The first mold surface of the molded portion 112, may be disposed on the first side of the first connector 116. The at least one molded via 114 may be electrically coupled to the first side of the first connector 116.

In an aspect of the present disclosure, the first connector 116 may have at least one metal pad 118. The at least one metal pad 118 may include a solder interconnect. The at least one metal pad 118 may be on the first side of the first connector 116. In an aspect, the at least one molded via 114 may be electrically coupled to the first side of the first connector 116 through the at least one metal pad 118.

In an aspect of the present disclosure, the second side of the first connector 116 may be configured for electrical connection to the second connector 128. In an aspect, there may be at least one conductive trace 131 between the first side of the first connector 116, and the second side of the first connector 116. The at least one conductive trace 131 may provide an electrical path between the first side of the first connector 116 and the second side of the first connector 116. In an aspect, the first side of the first connector 116 may be perpendicular to the second side of the first connector 116.

In an aspect of the present disclosure, the semiconductor system 100 may include a cable 130. The cable 130 may be connected to the second side of the first connector 116, and the second connector 128. The cable 130 may form an electrical connection between the first connector 116, and the second connector 128. The cable 130 may be a flexible printed circuit, a flat flexible cable, or a twin-axial cable. The cable 130 may have a first end and a second end. In an aspect, the first end of the cable 130 may have a first fastener attached to the first end. The second end of the cable 130 may have a second fastener attached to the second end. The first fastener of the cable 130 may be connected to the second side of the first connector 116. The second fastener of the cable 130 may be connected to the second connector 128.

In an aspect of the present disclosure, the first connector 116 may have a connector receptacle, e.g., a Type-C USB3 receptacle, or a fiber optic receptacle or a plug, e.g., a Type-C USB3 plug, or a fiber optic plug for electrical connection to another receptacle or another plug of the second connector 128 through the cable 130. In an aspect, the first fastener of the first end of the cable 130 may be a plug e.g., a Type-C USB3 plug, a flexible printed circuit cable plug, or a fiber optic connector plug or a receptacle, e.g., a Type-C USB3 receptacle, or a fiber optic connector receptacle. The first fastener of the first end of the cable 130, and the second side of the first connector 116 may be a receptacle-plug pair. In other words, if the first fastener is a receptacle, the second side of the first connector 116 is a plug, and if the first fastener is a plug, the second side of the first connector 116 is a receptacle. In an aspect, the second fastener of the second end of the cable 130 may have a receptacle, e.g., a Type-C USB3 receptacle or a plug, e.g., a Type-C USB3 plug, or a fiber optic connector plug. The second fastener of the second end of the cable 130, and the second connector 128 may be a receptacle-plug pair. In other words, if the second fastener is a receptacle, the second connector 128 is a plug, and if the second fastener is a plug, the second connector 128 is a receptacle.

In an aspect of the present disclosure, the cable 130 may include a first sub-cable and a second sub-cable. The first sub-cable may include a first dielectric material including a first set of dielectric properties e.g., a first dielectric loss tangent and/or a first dielectric constant. In an aspect, the second sub-cable may include a second dielectric material including a second set of dielectric properties e.g., a second dielectric loss tangent and/or a second dielectric constant different from the first dielectric material.

In an aspect, the first sub-cable may be configured to transmit high-speed signals may include a lower dielectric constant ranging approximately between 2.0 to 3.0, and a lower dielectric loss tangent ranging approximately between 0.001 to 0.007 compared to the second sub-cable which may be configured to transmit low-speed signals with a higher dielectric constant ranging approximately between 3.0 to 4.5, and a higher dielectric loss tangent ranging approximately between 0.008 to 0.03. In another aspect, the first sub-cable may be configured to transmit signals, and the second sub-cable may be configured to transmit power. In an aspect, each sub-cable may be configured to transmit signals of different speeds, and/or power of different voltage levels.

In an aspect of the present disclosure, the semiconductor system 100 may include a semiconductor device 122. In an aspect, the semiconductor device 122 may be made from any suitable semiconductor, such as silicon or gallium arsenide. The semiconductor device 122 may be a semiconductor die, a chip or a set of chiplets, e.g., a system-on-chip (SOC), a platform controller hub (PCH)/chipset, a memory device, a field programmable gate array (FPGA) device, a central processing unit (CPU), or a graphic processing unit (GPU). In the aspect shown in FIG. 1, the semiconductor device 122 may be a set of chiplets, which may include a first device 124A, e.g., a GPU, a second device 124B, e.g., a CPU, and a third device 124C, e.g., a memory.

In an aspect of the present disclosure, the semiconductor device 122 may be at least partially disposed on the interposer 108. The semiconductor device 122 may also be at least partially disposed on the molded portion 112. In an aspect, the semiconductor device 122 may have a first section disposed on the interposer 108. The semiconductor device 122 may have a second section disposed on the molded portion 112. As shown in FIG. 1, the second device 124B may be disposed on the interposer 108. A first section of the first device 124A may be disposed on the interposer. A second section of the first device 124A may be disposed on the molded portion 112. A first section of the third device 124C may be disposed on the interposer. A second section of the third device 124C may be disposed on the molded portion 112.

In an aspect of the present disclosure, the cable 130 may include a first reference plane and a second reference plane. The first reference plane and a second reference plane may be isolated by a dielectric layer to facilitate a direct PDN between the semiconductor device 122, and the power supply component disposed on the printed circuit board. In an aspect, the first reference plane may be associated with a first reference voltage e.g., a ground reference voltage (Vss). In an aspect, the second reference plane may be associated with a second reference voltage e.g., a power supply voltage (Vcc).

In an aspect of the present disclosure, a plurality of solder bumps 120 may be disposed on the molded portion 112. The plurality of solder bumps 120 may provide an electrical connection between the at least one molded via 114, and the semiconductor device 122. In an aspect, the at least one molded via 114 may be configured to transmit signals or power between the semiconductor device 122, and the first connector 116.

In an aspect of the present disclosure, the plurality of solder bumps 120 may be disposed on the interposer 108. The plurality of solder bumps 120 may be disposed on the interposer chiplet surface of the interposer 108. The plurality of solder bumps 120 may provide an electrical connection between the at least one TSV 110, and the semiconductor device 122. In an aspect, the at least one TSV 110 may be configured to transmit signals between the package substrate 102 and the semiconductor device 122. In an aspect of the present disclosure, at least a portion of the semiconductor device 122 may be electrically coupled to the package substrate 102 through the at least one TSV 110.

In an aspect of the present disclosure, an x-y dimension of the interposer 108 is independent of an x-y dimension of the semiconductor device 122. In an aspect, a width of the interposer 108 may be different than a width of the semiconductor device 122, e.g., the width of the interposer 108 may be smaller than the width of the semiconductor device 122. The difference in widths may be due to the first connector, and/or the molded portion 112 which may be at a periphery of the interposer 108.

In an aspect of the present disclosure, at least a portion of the semiconductor device 122 may be electrically coupled to the first connector 116 through the at least one molded via 114. In an aspect, at least one molded via 114 may be electrically coupled at a first end to the first device and may be at a second end to the first connector 116. In an aspect, at least a portion of the semiconductor device 122 may be disposed on the second mold surface of the molded portion 112. In an aspect, the first device may have a signal connection, e.g., a direct signal connection to the motherboard 105.

In an aspect of the present disclosure, the semiconductor device 122 which may include the first device 124A, the second device 124B, and the third device 124C may communicate with one another through an RDL 119 within the interposer 108. In an aspect, the RDL 119 may include a plurality of conductive traces interleaving with a plurality of dielectric layers. In further aspects, the RDL 119 is coupled to the at least one TSV 110 within the interposer 108. In an aspect, the semiconductor device 122 may pass signal I/O and/or power from the package substrate 102 between the first device 124A, the second device 124B, and the third device 124C through the RDL 119. For example, the second device 124B may obtain a signal I/O and/or power from the package substrate 102, and pass the signal I/O and/or power to the first device 124A through the RDL 119. In an aspect, the semiconductor device 122 may pass signal I/O and/or power from the second connector 128 between the first device 124A, the second device 124B, and the third device 124C through the RDL 119. For example, the first device 124A may obtain a signal I/O and/or power from the second connector 128, through the first connector 116, and may pass the signal I/O and/or power to the second device 124B through the RDL 119.

In an aspect of the present disclosure, the semiconductor device 122 may have a signal connection to the motherboard 105 through the first connector 116, the second connector 128, and the cable 130. In an aspect, the semiconductor device 122 may be connected to the motherboard 105 through the interposer 108, and the at least one TSV 110 within the interposer 108. In an aspect, due to the RC parasitic effects of the TSV transitions, high-speed signals may be passed through the first connector 116, the second connector 128, and the cable 130 instead of through the at least one TSV 110. Low speed signals may be passed through the at least one TSV 110.

In an aspect of the present disclosure, a thickness of the interposer 108 may be substantially similar to a combined thickness of the molded portion 112, and the first connector 116. In an aspect, the thickness of the interposer 108 may range from approximately 100 μm to 800 μm. The thickness of the molded portion 112 may range from approximately 20 μm to 200 μm. The thickness of the first connector 116 may range from approximately 80 μm to 600 μm.

In an aspect of the present disclosure, the package substrate 102 may have a recess. The first connector 116 may be disposed on the recess of the package substrate 102. The recess may be below the mold cavity. In an aspect, a thickness of the interposer 108 may be smaller than a combined thickness of the mold portion 112 and the first connector 116. The recess on the package substrate 102 may facilitate the difference in the thickness between the interposer 108 and the combined thickness of the molded portion 112 and the first connector 116. The recess on the package substrate 102 may result in additional space, which may allow the first connector 116 to fit between the molded portion 112, and the package substrate 102. The depth of the recess may be chosen based on the difference between the thickness of the interposer 108, and the combined thickness of the molded portion 112 and the first connector 116. The depth of the recess may range from approximately 100 μm to 300 μm.

In an aspect of the present disclosure, the semiconductor system 100 may include a second mold cavity in the molded portion. In an aspect, the semiconductor system 100 may include a third connector 116′. The third connector 116′ may be disposed in the second mold cavity and may be coupled to the molded portion. The interposer 108 may be in between the first connector 116, and the third connector 116′. The third device 124C may be positioned over the second mold cavity and coupled to the molded portion 112.

In an aspect of the present disclosure, the third connector 116′ may be an interposer connector. In an aspect, semiconductor system 100 may include an additional cable 130′. The additional cable may be coupled to the third connector 116′. In an aspect, the semiconductor system 100 may include a fourth connector 128′. The fourth connector 128′ may be positioned on and may be coupled to the motherboard 105 for a signal connection between the third device 124C and the motherboard 105. In an aspect, the third connector 116′ may be electrically coupled to the fourth connector 128′. The at least one additional cable 130′ may form an electrical connection between the third connector 116′, and the fourth connector 128′. In an aspect, the fourth connector 128′ may be electrically coupled to the voltage regulator 138.

For the sake of brevity, duplicate descriptions of features and properties are omitted. It will be understood that the descriptions of any description and/or feature and/or property relating to the first connector 116, the cable 130, and the second connector 128 will apply to the third connector 116′, the at least one additional cable 130′, and the fourth connector 128′.

In an aspect, the number of connectors for the semiconductor package may be any suitable integer n. In an aspect, the number of suitable integer n may be chosen based on the size of the connectors as well as the size of the package substrate. In an aspect, the number of suitable integer n may be chosen based on the number of different types of signals and/or the number of different power/voltages to be sent from the electrical component. It will be understood that the descriptions of any description and/or feature and/or property relating to the connector will apply to each of n connectors.

In an aspect, the number of cables for the semiconductor package may be any suitable integer m. In an aspect, the number of suitable integer m may be chosen based on the number of the connectors. In an aspect, the number of suitable integer m may be chosen based on the number of different types of signals and/or the number of different power/voltages to be sent from the electrical component. It will be understood that the descriptions of any description and/or feature and/or property relating to the cable 130 will apply to each of m cables.

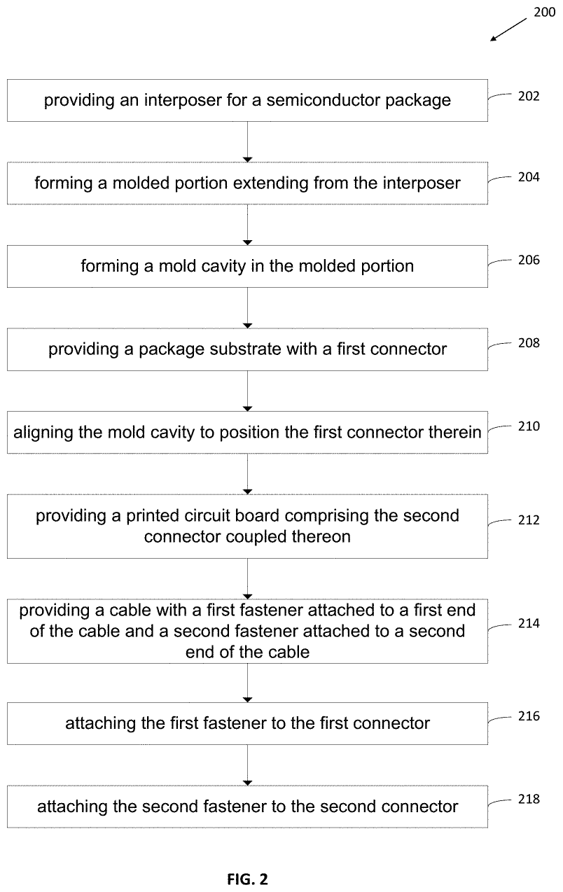

FIG. 2 shows a flow chart illustrating a method of forming a device according to an aspect of the present disclosure.

As shown in FIG. 2, there may be a method 200 of forming a device. In the method 200, a first operation 202 may include providing an interposer for a semiconductor package. In a second operation 204, a molded portion extending from the interposer may be formed. In a third operation 206, a mold cavity in the molded portion may be formed. In a fourth operation 208, a package substrate with a first connector may be provided. In a fifth operation 210, the mold cavity may be aligned to position the first connector therein. In a sixth operation 212, a printed circuit board may be provided. The printed circuit board may have the second connector coupled thereon. In a seventh operation 214, a cable with a first fastener attached to a first end of the cable and a second fastener attached to a second end of the cable may be provided. In an eighth operation 216, the first fastener may be attached to the first connector. In a ninth operation 218, the second fastener may be attached to the second connector.

It will be understood that the above operations described above relating to FIG. 2 are not limited to this particular order. Any suitable, modified order of operations may be used.

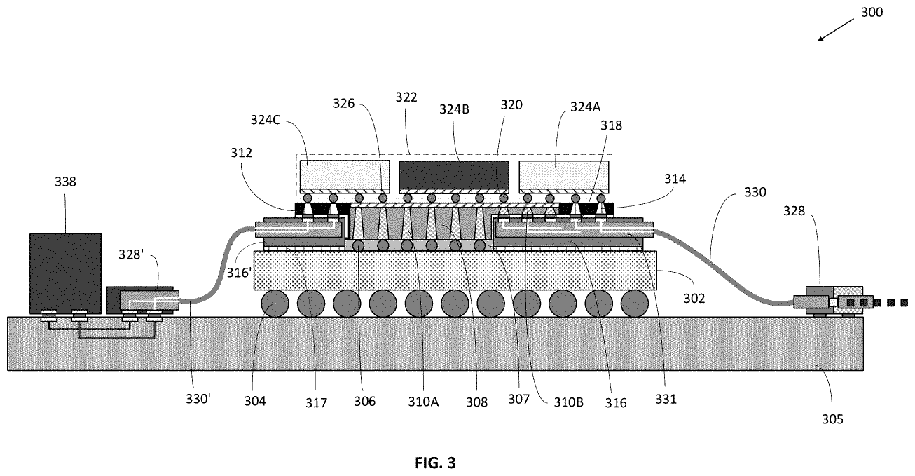

FIG. 3 shows a cross-sectional view of a semiconductor system according to an aspect of the present disclosure.

For the sake of brevity, duplicate descriptions of features and properties are omitted. It will be understood that the descriptions of any feature and/or property relating to FIG. 1 that are the same or similar to a feature and/or property in FIG. 3 will have those descriptions be applicable here as well.

In an aspect of the present disclosure, a semiconductor system 300 is shown in FIG. 3. In an aspect, the semiconductor system 300 may include a package substrate 302. In an aspect, the semiconductor system 300 may include a plurality of solder balls 304. The package substrate 302 may be connected to a motherboard 305 through the plurality of solder balls 304. In an aspect, the plurality of solder balls 304 may provide an electrical connection between the package substrate 302, and the motherboard 305. In an aspect of the present disclosure, the semiconductor system 300 may include a plurality of package bumps 306 disposed on the package substrate 302.

In an aspect of the present disclosure, the semiconductor system 300 may include an interposer 308. In an aspect, the interposer 308 may be disposed on the package substrate 302. In an aspect, the interposer 308 may be connected to the package substrate 302 through the plurality of package bumps 306. The plurality of package bumps 306 may also provide an electrical connection between the interposer 308, and the package substrate 302.

In an aspect of the present disclosure, the interposer 308 may include at least one TSV 310. The plurality of package bumps 306 may provide an electrical connection between the at least one TSV 310, and the package substrate 302. Each TSV 310 may be correspondingly coupled to a package bump 306 of the plurality of package bumps 306.

In an aspect of the present disclosure, the interposer 308 may have a first portion, and a second portion. In an aspect, the first portion of the interposer 308 may have a first TSV 310A. In an aspect, the second portion of the interposer 308 may have a second TSV 310B.

In an aspect of the present disclosure, the semiconductor system 300 may include a first connector 316. In an aspect, first connector 316 may be disposed on the package substrate 302. In an aspect, the first connector 316 may be attached to the package substrate 302 through an adhesive layer 317. In an aspect, the first connector 316 may be disposed adjacent to the interposer 308.

In an aspect of the present disclosure, the semiconductor system 300 may include a second connector 328. In an aspect, the second connector 328 may be mounted on the motherboard 305. In an aspect, the second connector 328 may be electrically connected to the motherboard 305. In an aspect, the second connector 328 may be an external connector, e.g., a passive connector, or a transceiver device. In an aspect, the second connector 328 may be connected to an external signal component. The external signal component may provide signals to the semiconductor system 300. In an aspect, the second connector 328 may be connected to a power supply component, e.g., a voltage regulator for reduced AC power loop inductance. The power supply component may be mounted on the motherboard 305.

In an aspect of the present disclosure, the semiconductor system 300 may include a molded portion 312. In an aspect, the molded portion 312 may be disposed on the first connector 316. In an aspect, the molded portion 312 may be disposed adjacent to the interposer 308. In an aspect, the molded portion 312 may be disposed at a periphery of the interposer 308. In an aspect, the molded portion 312 may have a mold cavity. In an aspect, the molded portion 312 may have a first portion, and a second portion. The first portion of the molded portion 312 may have a thickness larger than a thickness of the second portion of the molded portion 312. The first portion of the molded portion 312 may be disposed at a periphery of the interposer 308. The first portion of the molded portion 312 may surround at least one periphery side wall of the interposer 308. In an aspect, the mold cavity may be below the second portion of the molded portion 312. In an aspect, the first connector 316 may be positioned in the mold cavity. The first connector 316 may be coupled to the molded portion, e.g., to the second portion of the molded portion 312.

In an aspect of the present disclosure, the mold cavity may be a through mold cavity. The through mold cavity may extend through the first portion and the second portion of the molded portion 312. In an aspect, the interposer 308 may include an interposer cavity. The interposer cavity may be on a periphery of the through mold cavity. The through mold cavity may extend into the interposer cavity and may become a single cavity. The single cavity may extend through the molded portion 312, and at least a portion of the interposer 308. In an aspect, the first connector 316 may be positioned in the through mold cavity, and the interposer cavity.

In an aspect of the present disclosure, a thickness of the first portion of the interposer 308 may be larger than a thickness of the second portion of the interposer 308. In an aspect, a thickness of the first TSV 310A may be larger than a thickness of the second TSV 310B. In an aspect, the thickness of the second portion of the interposer 308 may be substantially similar to a thickness of the second portion of the molded portion 312.

In an aspect of the present disclosure, the first TSV 310A may be electrically coupled to the package substrate. In an aspect, the second TSV 310B may be electrically coupled to the first connector 316.

In an aspect of the present disclosure, the mold portion 312 may include at least one molded via 314. The mold portion 312 may have a first mold surface coupled to the first connector 316. The mold portion 312 may have a second mold surface coupled to the semiconductor device 322. In an aspect, the second mold surface may be adjacent to an interposer chiplet surface. In an aspect, the at least one molded via 314 may be embedded in the molding material of the mold portion 312. The at least one molded via 314 may extend through the first mold surface, and the second mold surface. In an aspect, the molded via 314 may be in the second portion of the molded portion 312.

In an aspect of the present disclosure, the first connector 316 may have a first side and a second side. The first mold surface of the molded portion 312, may be disposed on the first side of the first connector 316. The at least one molded via 314 may be electrically coupled to the first side of the first connector 316.

In an aspect of the present disclosure, the first connector 316 may have at least one metal pad 318. The at least one metal pad 318 may be on the first side of the first connector 316. In an aspect, the at least one molded via 314 may be electrically coupled to the first side of the first connector 316 through the at least one metal pad 318.

In an aspect of the present disclosure, the second side of the first connector 316 may be configured for electrical connection to a second connector 328. In an aspect, there may be at least one connector conductive trace 331 between the first side of the first connector 316, and the second side of the first connector 316. The at least one connector conductive trace 331 may provide an electrical path between the first side of the first connector 316 and the second side of the first connector 316. In an aspect, the first side of the first connector 316 may be perpendicular to the second side of the first connector 316.

In an aspect of the present disclosure, the semiconductor system 300 may include a cable 330. The cable 330 may be connected to the second side of the first connector 316, and the second connector 328. The cable 330 may form an electrical connection between the first connector 316, and the second connector 328. The cable 330 may be a flexible printed circuit, a flat flexible cable, or a twin-axial cable. The cable 330 may have a first end and a second end. In an aspect, the first end of the cable 330 may have a first fastener attached to the first end. The second end of the cable 330 may have a second fastener attached to the second end. The first fastener of the cable 330 may be connected to the second side of the first connector 316. The second fastener of the cable 330 may be connected to the second connector 328.

In an aspect of the present disclosure, the second side of the first connector 316 may have a connector receptacle, e.g., a Type-C USB3 receptacle, or a fiber optic receptacle or a plug, e.g., a Type-C USB3 plug, or a fiber optic plug for electrical connection to another receptacle or another plug of the second connector 328 through the cable 330. In an aspect, the first fastener of the first end of the cable 330 may be a plug e.g., a Type-C USB3 plug, a flexible printed circuit cable plug or a fiber optic connector plug or a receptacle, e.g., a Type-C USB3 receptacle, or a fiber optic connector receptacle. The first fastener of the first end of the cable 330, and the second side of the first connector 316 may be a receptacle-plug pair. In other words, if the first fastener is a receptacle, the second side of the first connector 316 is a plug, and if the first fastener is a plug, the second side of the first connector 316 is a receptacle. In an aspect, the second fastener of the second end of the cable 330 may have a receptacle, e.g., a Type-C USB3 receptacle or a plug, e.g., a Type-C USB3 plug, or a fiber optic connector plug. The second fastener of the second end of the cable 330, and the second connector 328 may be a receptacle-plug pair. In other words, if the second fastener is a receptacle, the second connector 328 is a plug, and if the second fastener is a plug, the second connector 328 is a receptacle.

In an aspect of the present disclosure, the cable 330 may include a first sub-cable and a second sub-cable. The first sub-cable may include a first dielectric material including a first set of dielectric properties, e.g., a first dielectric loss tangent and/or a first dielectric constant. In an aspect, the second sub-cable may include a second dielectric material including a second set of dielectric properties, e.g., a second dielectric loss tangent and/or a second dielectric constant different from the first dielectric material.

In an aspect, the first sub-cable may be configured to transmit high-speed signals may include a lower dielectric constant ranging approximately between 2.0 to 3.0, and a lower dielectric loss tangent ranging approximately between 0.001 to 0.007 compared to the second sub-cable which may be configured to transmit low-speed signals with a higher dielectric constant ranging approximately between 3.0 to 4.5, and a higher dielectric loss tangent ranging approximately between 0.008 to 0.03. In another aspect, the first sub-cable may be configured to transmit signals, and the second sub-cable may be configured to transmit power. In an aspect, each sub-cable may be configured to transmit signals of different speeds, and/or power of different voltage levels.

In an aspect of the present disclosure, the semiconductor system 300 may include semiconductor device 322. In the aspect shown in FIG. 3, the semiconductor device 322 may be a set of chiplets, which may include a first device 324A, e.g., a GPU, a second device 324B, e.g., a CPU, and a third device 324C, e.g., a memory.

In an aspect of the present disclosure, the semiconductor devices 322 may be at least partially disposed on the interposer 308. The semiconductor devices 322 may also be at least partially disposed on the molded portion 312. In an aspect, the semiconductor device 322 may have a first section disposed on the interposer 308. The semiconductor device 322 may have a second section disposed on the molded portion 312. As shown in FIG. 3, a first section of the first device 324A may be disposed on the interposer 308, and a second section of the first device 324A may be disposed on the molded portion 312. The second device 324B may be disposed on the interposer 308. A first section of the third device 324C may be disposed on the interposer 308, and a second section of the third device 324C may be disposed on the molded portion 312.

In an aspect of the present disclosure, the cable 330 may includes a first reference plane and a second reference plane. The first reference plane and a second reference plane may be isolated by a dielectric layer to facilitate a direct PDN between the semiconductor device 322, and the power supply component disposed on the printed circuit board. In an aspect, the first reference plane may be associated with a first reference voltage e.g., a ground reference voltage (Vss). In an aspect, the second reference plane may be associated with a second reference voltage e.g., a power supply voltage (Vcc).

In an aspect of the present disclosure, a plurality of solder bumps 320 may be disposed on the molded portion 312. The plurality of solder bumps 320 may provide an electrical connection between the at least one molded via 314, and the semiconductor device 322. In an aspect, the at least one molded via 314 may be configured to transmit signals or power between the semiconductor device 322, and the first connector 316.

In an aspect of the present disclosure, the plurality of solder bumps 320 may be disposed on the interposer 308. The plurality of solder bumps 320 may be disposed on the interposer chiplet surface of the interposer 308. The plurality of solder bumps 320 may provide an electrical connection between the at least one TSV 310, and the semiconductor device 322. In an aspect, the at least one TSV 310 may be configured to transmit signals between the package substrate 302 and the semiconductor device 322. In an aspect of the present disclosure, at least a portion of the semiconductor device 322 may be electrically coupled to the package substrate 302 through the at least one TSV 310.

In an aspect of the present disclosure, an x-y dimension of the interposer 308 is independent of an x-y dimension of the semiconductor devices 322. In an aspect, a width of the interposer 308 may be different than a width of the semiconductor devices 322, e.g., the width of the interposer 308 may be smaller than the width of the semiconductor devices 322. The difference in widths may be due to the first connector 316, and/or the molded portion 312 which may be at a periphery of the interposer 308.

In an aspect of the present disclosure, at least a portion of the semiconductor devices 322 may be electrically coupled to the first connector 316 through the at least one molded via 314. In an aspect, the at least one molded via 314 may be electrically coupled at a first end to the first device and may be at a second end to the first connector 316. In an aspect, at least a portion of the semiconductor device 322 may be disposed on the second mold surface of the molded portion 312. In an aspect, the first device may have a signal connection, e.g., a direct signal connection to the motherboard 305.

In an aspect of the present disclosure, at least a portion of the semiconductor devices 322 may be electrically coupled to the first connector 316 through the second TSV 310B. In an aspect, the second TSV 310B may be electrically coupled at a first end to the second device and may be electrically coupled at a second end to the first connector 316. In an aspect, the second device may have a signal connection, e.g., a direct signal connection to the motherboard 105.

In an aspect of the present disclosure, the semiconductor device 322 which may include the first device 324A, the second device 324B, and the third device 324C may communicate with one another through an RDL 319 within the interposer 308. In an aspect, the RDL 319 may include a plurality of conductive traces interleaving with a plurality of dielectric layers. In further aspects, the RDL 319 is coupled to the at least one TSV 310 within the interposer 308. In an aspect, the semiconductor device 322 may pass signal I/O and/or power from the package substrate 302 between the first device 324A, the second device 324B, and the third device 324C through the RDL 319. For example, the second device 324B may obtain a signal I/O and/or power from the package substrate 302, and pass the signal I/O and/or power to the first device 324A through the RDL 319. In an aspect, the semiconductor device 322 may pass signal I/O and/or power from the second connector 328 between the first device 324A, the second device 324B, and the third device 324C through the RDL 319. For example, the first device 324A may obtain a signal I/O and/or power from the second connector 328, through the first connector 316, and may pass the signal I/O and/or power to the second device 324B through the RDL 319.

In an aspect of the present disclosure, the semiconductor device 322 may have a signal connection to the motherboard 305 through the first connector 316, the second connector 328, and the cable 330. In an aspect, the semiconductor device 322 may be connected to the motherboard 305 through the interposer 308, and the at least one TSV 310 within the interposer 308. In an aspect, due to the RC parasitic effects of the TSV transitions, high-speed signals may be passed through the first connector 316, the second connector 328, and the cable 330 instead of through the at least one TSV 310. Low speed signals may be passed through the TSV 310.

In an aspect of the present disclosure, the package substrate 302 may have a recess (not shown). The recess may be below the mold cavity. The first connector 316 may be disposed on the recess of the package substrate 302. In an aspect, a thickness of the interposer 308 may be smaller than a combined thickness of the molded portion 312, and the first connector 316. The recess on the package substrate 302 may facilitate the difference in the thickness between the interposer 308, and the combined thickness of the molded portion 312, and the first connector 316. The recess on the package substrate 302 may result in additional space, which may allow the first connector 316 to fit between the molded portion 312, and the package substrate 302. The depth of the recess may be chosen based on the difference between the thickness of the interposer 308, and the combined thickness of the molded portion 312 and the first connector 316.

In an aspect of the present disclosure, the semiconductor system 300 may include a second mold cavity in the molded portion. In an aspect, the semiconductor system 300 may include a third connector 316′. The third connector 316′ may be disposed in the second mold cavity and may be coupled to the molded portion. The interposer 308 may be in between the first connector 316, and the third connector 316′. The third device 324C may be positioned over the second mold cavity and coupled to the molded portion 312.

In an aspect of the present disclosure, the semiconductor system 300 may include an additional cable 330′. The additional cable may be coupled to the third connector 316′. In an aspect, the semiconductor system 300 may include a fourth connector 328′. The fourth connector 328′ may be positioned on and may be coupled to the motherboard 305 for a signal connection, e.g., a direct signal connection, between the third device 324C, and the motherboard 305. In an aspect, the third connector 316′ may be electrically coupled to the fourth connector 328′. The at least one additional cable 330′ may form an electrical connection between the third connector 316′, and the fourth connector 328′.

For the sake of brevity, duplicate descriptions of features and properties are omitted. It will be understood that the descriptions of any description and/or feature and/or property relating to the first connector 316, the cable 330, and the second connector 328 will apply to the third connector 316′, the at least one additional cable 330′, and the fourth connector 328′.

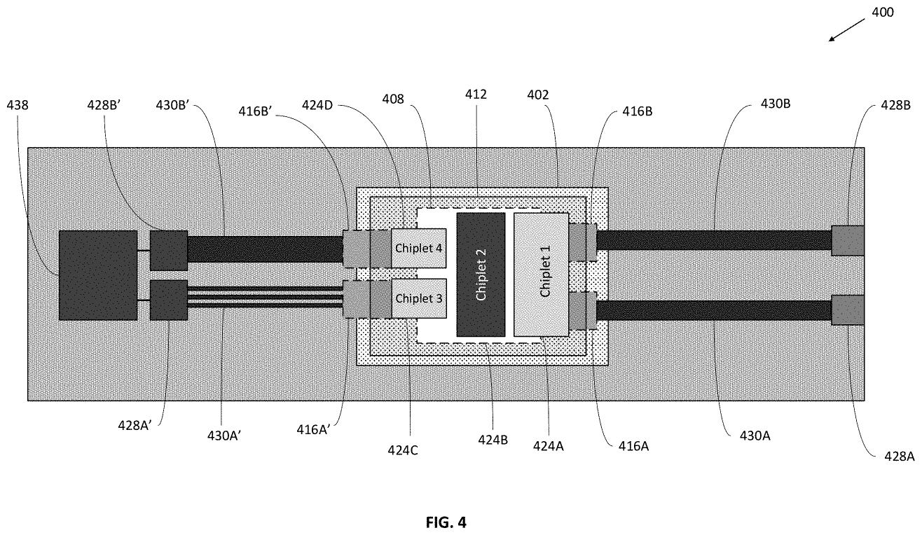

FIG. 4 shows a top view of the semiconductor system of FIG. 3 according to an aspect of the present disclosure.

For the sake of brevity, duplicate descriptions of features and properties are omitted. It will be understood that the descriptions of any feature and/or property relating to FIGS. 1 and 3 that are the same or similar to a feature and/or property in FIG. 4 will have those descriptions be applicable here as well.

In an aspect of the present disclosure, a semiconductor system 400 is shown in FIG. 4. In an aspect, the semiconductor system 400 may include a package substrate 402. In an aspect, the semiconductor system 400 may include an interposer 408. In an aspect, the interposer 408 may be disposed on the package substrate 402.

In an aspect of the present disclosure, the semiconductor system 400 may include a first connector 416A, and/or a second connector 428A. In an aspect, the first connector 416A may be disposed on the package substrate 402. The second connector 428A may be disposed on a motherboard. The motherboard may be a PCB.

In an aspect of the present disclosure, the semiconductor system 400 may include a third connector 416B, and/or a fourth connector 428B. In an aspect, the third connector 416B may be disposed on the package substrate 402. The fourth connector 428B may be disposed on a motherboard. The motherboard may be a PCB.

In an aspect of the present disclosure, the semiconductor system 400 may include a molded portion 412. In an aspect, the molded portion 412 may be disposed on the first connector 416A and/or the third connector 416B. In an aspect, the molded portion 412 may be disposed adjacent to the interposer 408. In an aspect, the molded portion 412 may be disposed at a periphery of the interposer 408.

In an aspect of the present disclosure, the semiconductor system 400 may include semiconductor devices. The semiconductor device may be a set of chiplets, which may include a first device 424A, a second device 424B, a third device 424C, and a fourth device 424D.

In an aspect of the present disclosure, the semiconductor device may be at least partially disposed on the interposer 408. The semiconductor device may also be at least partially disposed on the molded portion 412. In an aspect, the semiconductor device may have a first section disposed on the interposer 408. The semiconductor device may have a second section disposed on the molded portion 412. The first device 424A may be partially disposed on the interposer 408 and may be partially disposed on the molded portion 412. The second device 424B may be disposed on the interposer 408. The third device 424C and the fourth device 424D may be partially disposed on the interposer 408 and may be partially disposed on the molded portion 412.

In an aspect of the present disclosure, the semiconductor system 400 may include a first cable 430A. The first cable 430A may be connected to the first connector 416A and the second connector 428A. In an aspect, the semiconductor system 400 may include a second cable 430B. The second cable 430B may be connected to the third connector 416B and the fourth connector 428B. Alternatively, both the first cable 430A, and the second cable 430B may be connected to the second connector 428A, or both the first cable 430A and the second cable 430B may be connected to the fourth connector 428B.

In an aspect of the present disclosure, the first cable 430A, and/or the second cable 430B may includes a first reference plane and a second reference plane. The first reference plane and a second reference plane may be isolated by a dielectric layer to facilitate a direct PDN between the semiconductor device, and a power supply component disposed on the printed circuit board. In an aspect, the first reference plane may be associated with a first reference voltage e.g., a ground reference voltage (Vss). In an aspect, the second reference plane may be associated with a second reference voltage e.g., a power supply voltage (Vcc).

In an aspect of the present disclosure, the first connector 416A, and/or the third connector 416B may have a receptacle or a plug for electrical connection to another receptacle or another plug of the second connector 428A and/or the fourth connector 428B. In an aspect, the first cable 430A, and/or the second cable 430B may have a receptacle or a plug. The first cable 430A, and/or the second cable 430B, and the first connector 416A, and/or the third connector 416B may be a receptacle-plug pair. In an aspect, the first cable 430A, and/or the second cable 430B, and the second connector 428A, and/or the fourth connector 428B may be a receptacle-plug pair.

In an aspect of the present disclosure, the first cable 430A may include a first dielectric material including a first dielectric properties e.g., a first dielectric loss tangent and/or a first dielectric constant. In an aspect, the second cable 430B may include a second dielectric material including a second dielectric properties e.g., a second dielectric loss tangent and/or a second dielectric constant different from the first dielectric material.

In an aspect, a first cable 430A may be configured to transmit high-speed signals may include a lower dielectric constant ranging approximately between 2.0 to 3.0, and a lower dielectric loss tangent ranging approximately between 0.001 to 0.007 compared to the second cable 430B which may be configured to transmit low-speed signals with a higher dielectric constant ranging approximately between 3.0 to 4.5, and a higher dielectric loss tangent ranging approximately between 0.008 to 0.03. In another aspect, the first connector 416A may be configured to transmit signals, and the third connector 416B may be configured to transmit power.

In an aspect, the first cable 430A, and/or the second cable 430B may include a plurality of sub-cables. Each sub-cable of the plurality of sub-cables may be configured to transmit signals of different speeds, and/or power of different voltage levels.

In an aspect of the present disclosure, the semiconductor system 400 may include a first additional connector 416A′, and a second additional connector 428A′. The interposer 408 may be in between the first connector 416A, and the first additional connector 416A′.

In an aspect of the present disclosure, the semiconductor system 400 may include a third additional connector 416B′, and a fourth additional connector 428B′. The interposer 408 may be in between the third connector 416B, and the third additional connector 416B′.

In an aspect of the present disclosure, the semiconductor system 400 may include a first additional cable 430A′. The first additional cable 430A′ may be connected to the first additional connector 416A′, and the second additional connector 428A′.

In an aspect, the semiconductor system 400 may include a second additional cable 430B′. The second additional cable 430B′ may be connected to the third additional connector 416B′, and a fourth additional connector 428B′. Alternatively, both the first additional cable 430A′, and the second additional cable 430B′ may be connected to the second additional connector 428A′, or both the first additional cable 430A′, and the second additional cable 430B′ may be connected to the fourth additional connector 428B′. In an aspect, the first additional connector 416A′ and/or the third additional connector 416B′ may be electrically coupled to the voltage regulator 438.

For the sake of brevity, duplicate descriptions of features and properties are omitted. It will be understood that the descriptions of any description and/or feature and/or property relating to the first connector 416A, the third connector 416B, the first cable 430A, the second cable 430B, the second connector 428A, and the fourth connector 428B will apply to the first additional connector 416A′, the third additional connector 416B′, the first additional cable 430A′, the second additional cable 430B′, the second additional connector 428A′, and the fourth additional connector 428B′.

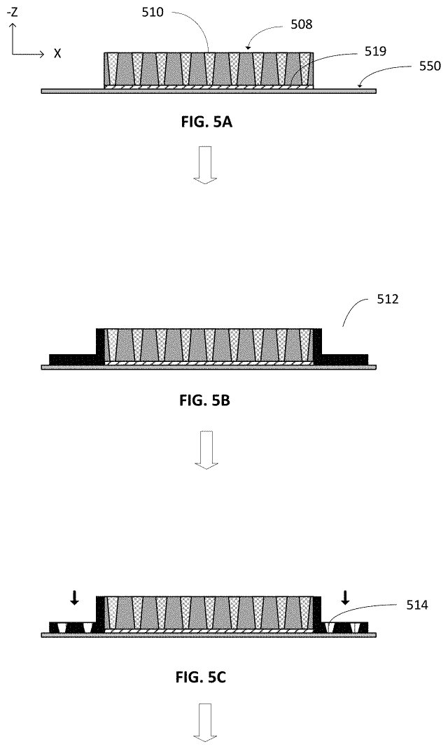

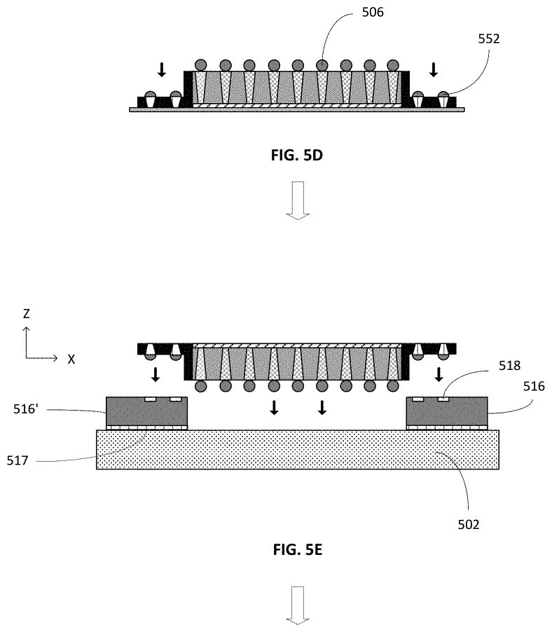

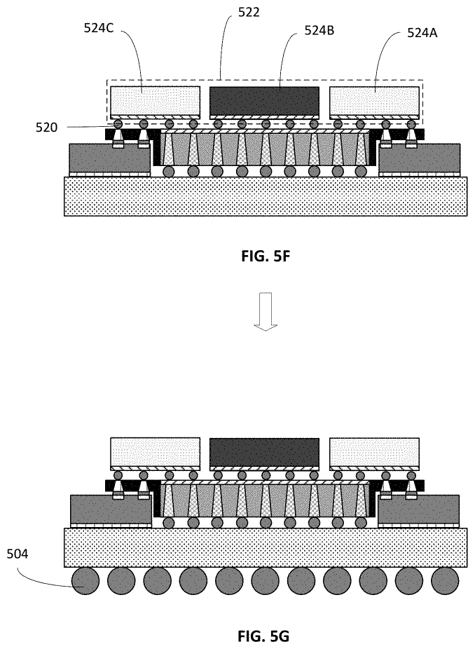

FIGS. 5A through 5G show cross-sectional views directed to an exemplary process flow for a method of forming a semiconductor system according to an aspect of the present disclosure.

As shown in FIG. 5A, an interposer 508 with an RDL 519 may be disposed on a carrier 550. The RDL 519 may be a plurality of metal layers. The RDL 519 may be made of copper, silver, or aluminum layers with a dielectric layer therebetween. The RDL 519 may be disposed on the interposer 508 through a photolithography, an etching and/or an electroplating process. The interposer 508 may be disposed on the carrier 550 through a lamination, a hot-press and/or a mechanical attachment process. At least one TSV 510 may be pre-formed in the interposer 508 before the interposer 508 is disposed on the carrier 550. The interposer 508 may be an active or passive silicon interposer.

As shown in FIG. 5B, a mold layer 512 may be formed at a periphery of the interposer 508. The mold layer 512 may be a stepped mold layer. The mold layer may have a first section and a second section. A thickness of the first section of the mold layer 512 may be larger than a thickness of the second section of the mold layer 512. The thickness of the first section of the mold layer 512 may be substantially similar to a thickness of the interposer 508. The mold layer 512 may be formed through compression, injection and/or by a transfer molding process.

As shown in FIG. 5C, a plurality of via openings may be formed in the mold layer 512 using mechanical drilling and/or laser drilling. The plurality of via openings may be formed in the second section of the mold layer 512. A conductive material may be deposited in the plurality of via openings, to form a plurality of molded vias 514. The conductive material may be deposited using an electroless and/or electroplating process.

As shown in FIG. 5D, a plurality of package bumps 506 may be disposed on the interposer 508. Each package bump 506 may be correspondingly coupled to each TSV 510. A plurality of solder interconnects 552 may be disposed on the mold layer 512. Each solder interconnect 552 may be correspondingly coupled to each molded via 514. A molded integrated interposer may be formed. The molded integrated interposer may be a single component/structure including the interposer 508, and the mold layer 512.

As shown in FIG. 5E, a package substrate 502 may be prepared according to conventional methods. A first connector 516 may be disposed on a package substrate 502. An adhesive layer 517 may couple the first connector 516 on the package substrate 502. The first connector 516 may have metal pads 518. A third connector 516′ may be disposed on the package substrate 502 and may be coupled to the package substrate 502 by the adhesive layer 517. The molded integrated interposer of FIG. 5D may be flipped over. The flipped molded integrated interposer may be disposed on the package substrate 502, the first connector 516, and the third connector 516′. The plurality of package bumps 506 may be disposed on the package substrate 502. The interposer 508 may be electrically connected to the package substrate 502 through the plurality of package bumps 506. The solder interconnects 552 may be disposed on the metal pads 518. The molded via 514 may be electrically connected to the first connector 516, and/or the third connector 516′ through the solder interconnects 552.

As shown in FIG. 5F, a plurality of solder bumps 520 may be disposed on the flipped molded integrated interposer, the mold layer 512, and the interposer 508. Semiconductor device 522 may be disposed on the plurality of solder bumps 520. The semiconductor device 522 may include a set of chiplets including a first device 524A, a second device 524B, and a third device 524C.

As shown in FIG. 5G, the package substrate 502 may have solder balls 504 on the opposing surface for connection to a motherboard. In addition, an underfill may be provided using either a conventional underfilling process and/or no-flow underfilling process to reduce the effects of thermal expansion.

It will be understood that the exemplary process described above relating to FIGS. 5A through 5G are not limited to this particular order. Any suitable, modified order of operations may be used.

Aspects of the present disclosure may be implemented into a system using any suitable hardware and/or software.

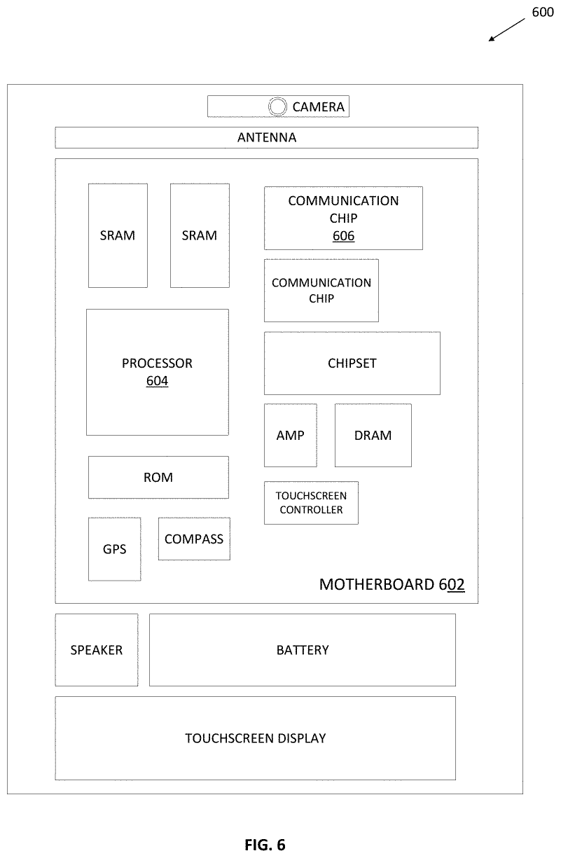

FIG. 6 schematically illustrates a computing device 600 that may include a semiconductor system as described herein, in accordance with some aspects.

As shown in FIG. 6, the computing device 600 may house a board such as a motherboard 602. The motherboard 602 may include a number of components, including but not limited to a processor 604 and at least one communication chip 606. The processor 604 may be physically and electrically coupled to the motherboard 602. In some implementations, the at least one communication chip 606 may also be physically and electrically coupled to the motherboard 602. In further implementations, the communication chip 606 may be part of the processor 604.

Depending on its applications, computing device 600 may include other components that may or may not be physically and electrically coupled to the motherboard 602. These other components may include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth). In another aspect, the processor 604 of the computing device 600 may be packaged in a semiconductor package, as described herein, and/or other semiconductor devices may be packaged together in a semiconductor package as described herein.

The communication chip 606 may enable wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some aspects they might not. The communication chip 606 may implement any of a number of wireless standards or protocols, including but not limited to Institute for Electrical and Electronics Engineers (IEEE) standards including Wi-Fi (IEEE 502.11 family), IEEE 502.16 standards (e.g., IEEE 502.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 502.16 compatible BWA networks are generally referred to as WiMAX networks, an acronym that stands for Worldwide Interoperability for Microwave Access, which is a certification mark for products that pass conformity and interoperability tests for the IEEE 502.16 standards.

The communication chip 606 may also operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 606 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 606 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 606 may operate in accordance with other wireless protocols in other aspects.

The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

In various implementations, the computing device 600 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In an aspect, the computing device 600 may be a mobile computing device. In further implementations, the computing device 600 may be any other electronic device that processes data.

### Examples

Example 1 may include a device including a printed circuit board; a semiconductor package including an interposer with a molded portion, and one or more of semiconductor devices, the one or more semiconductor devices including at least a first device coupled to the molded portion; and a first connector coupled to the molded portion, and a second connector coupled to the printed circuit board, the first connector and the second connector configured to be connected with a cable for signal connection between the first device and the printed circuit board.

Example 2 may include the device of example 1 and/or any other example disclosed herein in which the molded portion further includes: a mold cavity, wherein the first connector is disposed in the mold cavity; and at least one molded via electrically coupled at a first end to the first device and at a second end to the first connector.

Example 3 may include the device of example 2 and/or any other example disclosed herein in which the semiconductor package further includes: a package substrate, wherein the interposer with the molded portion and the first connector are disposed on the package substrate.

Example 4 may include the device of example 2 and/or any other example disclosed herein in which the first device further includes: a first section disposed on the interposer; and a second section disposed on the molded portion, wherein the first section is electrically coupled to the printed circuit board through the interposer and the second section is electrically coupled to the printed circuit board through the at least one molded via and the package connector.

Example 5 may include the device of example 2 and/or any other example disclosed herein in which the cable further includes: a first end including a first fastener connected to the first connector; and a second end including a second fastener connected to the second connector on the printed circuit board; and the second connector is coupled to an electrical component on the printed circuit board.

Example 6 may include the device of example 3 and/or any other example disclosed herein in which

Example 7 may include the device of example 1 and/or any other example disclosed herein in which the device further includes a recess below the mold cavity on the package substrate, wherein the first connector is disposed on the recess.

Example 8 may include the device of example 2 and/or any other example disclosed herein in which the cable includes a first sub-cable and a second sub-cable; wherein the first sub-cable is configured to transmit low-speed signals, and the second sub-cable is configured to transmit high-speed signals or a converse configuration.

Example 9 may include the device of example 8 and/or any other example disclosed herein in which the interposer further includes: a first portion including a first through-silicon-via electrically coupled to the package substrate; and a second portion including a second through-silicon-via electrically coupled to the first connector in the interposer cavity.

Example 10 may include the device of example 5 and/or any other example disclosed herein in which the device further includes a second mold cavity in the molded portion; a third connector positioned in the second mold cavity and coupled to the molded portion; a second device positioned over the second mold cavity and coupled to the molded portion; and an additional cable coupled to the third connector and to a fourth connector positioned on and coupled to the printed circuit board for a direct signal connection between the second device and the printed circuit board.

Example 11 may include a method including providing an interposer for a semiconductor package; forming a molded portion extending from the interposer; forming a mold cavity in the molded portion; providing a package substrate with a first connector; aligning the mold cavity to position the first connector therein; providing a printed circuit board including the second connector coupled thereon; providing a cable with a first fastener attached to a first end of the cable and a second fastener attached to a second end of the cable; attaching the first fastener to the first connector; and attaching the second fastener to the second connector.

Example 12 may include the method of example 11 and/or any other example disclosed herein in which the method further includes forming at least one molded via in the molded portion coupled with the first connector.

Example 13 may include the method of example 12 and/or any other example disclosed herein in which the method further includes disposing the interposer with the molded portion and the first connector on the package substrate; and disposing one or more semiconductor devices on the interposer and molded portion.

Example 14 may include the method of example 13 and/or any other example disclosed herein in which the one or more semiconductor devices includes at least a first device including a first section and a second section; disposing the first section on the interposer, and the second section on the molded portion; electrically connecting the first section to the printed circuit board through the interposer; and electrically connecting the second section to the printed circuit board through the at least one molded via and the first connector.

Example 15 may include the method of example 11 and/or any other example disclosed herein in which the method further includes providing a recess below the mold cavity on the package substrate; and disposing the first component on the recess.

Example 16 may include the method of example 11 and/or any other example disclosed herein in which forming the mold cavity further includes extending the mold cavity into an interposer cavity in the interposer; and positioning the first connector in the mold cavity and the interposer cavity.

Example 17 may include the method of example 16 and/or any other example disclosed herein in which the method further includes forming a first through silicon via in a first portion of the interposer; electrically coupling the first through-silicon-via to the package substrate; providing a second through silicon via in a second portion of the interposer; and electrically coupling the second through silicon via to the first connector.

Example 18 may include the method of example 13 and/or any other example disclosed herein in which the method further includes forming a second mold cavity in the molded portion; providing a third connector in the second mold cavity and coupling the third connector to the molded portion; positioning a second device of the one or more semiconductor devices over the second mold cavity and coupling the second device to the molded portion; providing a fourth connector on and coupled to the printed circuit board; and coupling an additional cable to the third connector and to the fourth connector for signal connection between the second device and the printed circuit board.

Example 19 may include a computing device including a printed circuit board coupled to the computing device; a semiconductor package including an interposer with a molded portion, and one or more of semiconductor devices, the one or more semiconductor devices including at least a first device coupled to the molded portion; and a first connector coupled to the molded portion, and a second connector coupled to the printed circuit board, the first connector and the second connector configured to be connected with a cable for signal connection between the first device and the printed circuit board.

Example 20 may include the computing device of example 19 and/or any other example disclosed herein in which the molded portion further includes: a mold cavity, wherein the first connector is disposed in the mold cavity; and at least one molded via electrically coupled at a first end to the first device and at a second end to the first connector.

These and other advantages and features of the aspects herein disclosed will be apparent through reference to the following description and the accompanying drawings. Furthermore, it is to be understood that the features of the various aspects described herein are not mutually exclusive and can exist in various combinations and permutations.

It will be understood that any property described herein for a specific system or device may also hold for any system or device described herein. It will also be understood that any property described herein for a specific method may hold for any of the methods described herein. Furthermore, it will be understood that for any device, system, or method described herein, not necessarily all the components or operations described will be enclosed in the device, system, or method, but only some (but not all) components or operations may be enclosed.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

While the present disclosure has been particularly shown and described with reference to specific aspects, it should be understood by those skilled in the art that various changes in form and detail may be made therein without departing from the scope of the present disclosure as defined by the appended claims. The scope of the present disclosure is thus indicated by the appended claims and all changes which come within the meaning and range of equivalency of the claims are therefore intended to be embraced.

What is claimed is:

1. A device comprising:
a printed circuit board;
a semiconductor package comprising an interposer with a molded portion, and one or more of semiconductor devices, the one or more semiconductor devices comprising at least a first device coupled to the molded portion; and
a first connector coupled to the molded portion, and a second connector coupled to the printed circuit board, the first connector and the second connector configured to be connected with a cable for signal connection between the first device and the printed circuit board.

2. The device of claim 1, wherein the molded portion further comprises:
a mold cavity, wherein the first connector is disposed in the mold cavity; and
at least one molded via electrically coupled at a first end to the first device and at a second end to the first connector.

3. The device of claim 2, wherein the semiconductor package further comprises:
a package substrate, wherein the interposer with the molded portion and the first connector are disposed on the package substrate.

4. The device of claim 2, wherein the first device further comprises:
a first section disposed on the interposer; and
a second section disposed on the molded portion, wherein the first section is electrically coupled to the printed circuit board through the interposer and the second section is electrically coupled to the printed circuit board through the at least one molded via and the package connector.

5. The device of claim 2, wherein the cable further comprises:
a first end comprising a first fastener connected to the first connector; and
a second end comprising a second fastener connected to the second connector on the printed circuit board; and
the second connector is coupled to an electrical component on the printed circuit board.

6. The device of claim 3, further comprising:
a recess below the mold cavity on the package substrate, wherein the first connector is disposed on the recess.

7. The device of claim 1,
wherein the cable comprises a first sub-cable and a second sub-cable;
wherein the first sub-cable is configured to transmit low-speed signals, and the second sub-cable is configured to transmit high-speed signals or a converse configuration.

8. The device of claim 2, wherein the mold cavity extends into an interposer cavity in the interposer, and wherein the first connector is positioned in the mold cavity and the interposer cavity.

9. The device of claim 8, wherein the interposer further comprises:
a first portion comprising a first through-silicon-via electrically coupled to the package substrate; and
a second portion comprising a second through-silicon-via electrically coupled to the first connector in the interposer cavity.

10. The device of claim 5, further comprising:
a second mold cavity in the molded portion;
a third connector positioned in the second mold cavity and coupled to the molded portion;
a second device positioned over the second mold cavity and coupled to the molded portion; and
an additional cable coupled to the third connector and to a fourth connector positioned on and coupled to the printed circuit board for a direct signal connection between the second device and the printed circuit board.

11. A method comprising:
providing an interposer for a semiconductor package;
forming a molded portion extending from the interposer;
forming a mold cavity in the molded portion;
providing a package substrate with a first connector;
aligning the mold cavity to position the first connector therein;
providing a printed circuit board comprising the second connector coupled thereon;
providing a cable with a first fastener attached to a first end of the cable and a second fastener attached to a second end of the cable;
attaching the first fastener to the first connector; and
attaching the second fastener to the second connector.

12. The method of claim 11, further comprising:
forming at least one molded via in the molded portion coupled with the first connector.

13. The method of claim 12, further comprising:
disposing the interposer with the molded portion and the first connector on the package substrate; and
disposing one or more semiconductor devices on the interposer and molded portion.

14. The method of claim 13, wherein the one or more semiconductor devices comprises at least a first device comprising a first section and a second section;
disposing the first section on the interposer, and the second section on the molded portion;
electrically connecting the first section to the printed circuit board through the interposer; and
electrically connecting the second section to the printed circuit board through the at least one molded via and the first connector.

15. The method of claim 11, further comprising:
providing a recess below the mold cavity on the package substrate; and
disposing the first component on the recess.

16. The method of claim 11, wherein forming the mold cavity further comprising:
extending the mold cavity into an interposer cavity in the interposer; and
positioning the first connector in the mold cavity and the interposer cavity.

17. The method of claim 16, further comprising:
forming a first through silicon via in a first portion of the interposer;
electrically coupling the first through-silicon-via to the package substrate;
providing a second through silicon via in a second portion of the interposer; and
electrically coupling the second through silicon via to the first connector.

18. The method of claim 13, further comprising:
forming a second mold cavity in the molded portion;
providing a third connector in the second mold cavity and coupling the third connector to the molded portion;
positioning a second device of the one or more semiconductor devices over the second mold cavity and coupling the second device to the molded portion;
providing a fourth connector on and coupled to the printed circuit board; and
coupling an additional cable to the third connector and to the fourth connector for signal connection between the second device and the printed circuit board.

19. A computing device comprising:
a printed circuit board coupled to the computing device;
a semiconductor package comprising an interposer with a molded portion, and one or more of semiconductor devices, the one or more semiconductor devices comprising at least a first device coupled to the molded portion; and
a first connector coupled to the molded portion, and a second connector coupled to the printed circuit board, the first connector and the second connector configured to be connected with a cable for signal connection between the first device and the printed circuit board.

20. The computing device of claim 19, wherein the molded portion further comprises:
a mold cavity, wherein the first connector is disposed in the mold cavity; and
at least one molded via electrically coupled at a first end to the first device and at a second end to the first connector.
